(19) United States
(12) Patent Application Publication
(10) Pub. No.: US 2026/0198086 A1
(43) Pub. Date: Jul. 9, 2026

(54) METHOD AND STRUCTURE OF AVOIDING GATE CONNECTOR TO BOTTOM SOURCE/DRAIN CONTACT SHORT

(71) Applicant: International Business Machines Corporation, Armonk, NY (US)

(72) Inventors: Eunsoo Cho, Albany, NY (US); Ruilong Xie, Niskayuna, NY (US); Chen Zhang, Santa Clara, CA (US); Shay Reboh, Albany, NY (US); Tenko Yamashita, Schenectady, NY (US); Thanh Nguyen, Troy, NY (US); Kamal Rudra, Albany, NY (US)

(21) Appl. No.: 19/010,524

(22) Filed: Jan. 6, 2025

(51) Int. Cl. H10D 84/85; H10D 84/01

(52) U.S. Cl. CPC H10D 84/856; H10D 84/0186; H10D 84/851

(57) ABSTRACT

A vertically stacked transistor component having a top active region shifted with respect to a bottom active region is presented. A gate connector is used to connect a top gate to a bottom gate. A bottom source/drain contact via is etched through a gate connector partially, but the bottom source/drain contact itself is electronically isolated from the gate connector by a self-aligned isolation layer located within the bottom source/drain contact via.

### BACKGROUND

The present disclosure relates to the electrical, electronic, and computer fields. In particular, the present disclosure relates to components and methods for avoiding a gate connector to CR (bottom source drain contact) short.

As the size of microelectronics decreases tolerances become more stringent. For example, between layers which can become misaligned sometimes cumulatively. Consequently, misalignment between layers and their structural features becomes more problematic, including the risk of short circuiting between electronically conductive structures.

### SUMMARY

According to one illustrative embodiment, a vertically stacked transistor component is provided. The vertically stacked transistor component, comprises a first layer comprising a first active region; a second layer coupled beneath the first layer, the second layer comprising a second active region, wherein the second active region is shifted with respect to the first active region; a bottom source/drain contact via partially etched through a gate connector located in the second layer; a self-aligned isolation liner located within the bottom source/drain contact via; and a bottom source/drain contact located within the self-aligned isolation liner, wherein the bottom source/drain contact is electronically isolated from the gate connector by the self-aligned isolation liner.

According to another illustrative embodiment, a semiconductor device is provided. The semiconductor device, comprises a first layer comprising a first active region; a second layer coupled beneath the first layer, the second layer comprising a second active region, wherein the second active region is shifted with respect to the first active region; a bottom contact via partially etched through a connector located in the second layer; a self-aligned isolation liner located within the bottom contact via; and a contact located within the self-aligned isolation liner, wherein the contact is electronically isolated from the connector by the self-aligned isolation liner.

According to another illustrative embodiment, a method of making a vertically stacked transistor component is provided. The method comprises forming a bottom device layer on a substrate, the bottom device layer comprising a bottom active region; forming top device layer on the bottom device layer, the top device layer comprising a top active region, wherein the bottom active region is laterally shifted with respect to the first active region; forming a bottom source/drain contact via partially etched through a gate connector located in the bottom layer; and forming a self-aligned isolation liner within the bottom source/drain contact via, wherein the bottom source/drain contact is electronically isolated from the gate connector by the self-aligned isolation liner.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

FIGS. 1A-1D illustrate 4 views of an example of a component following the performance of a portion of a process flow, in accordance with embodiments of the present disclosure.

FIGS. 2A-2D illustrate 4 views of an example of a component following the performance of a portion of a process flow, in accordance with embodiments of the present disclosure.

FIGS. 3A-3D illustrate 4 views of an example of a component following the performance of a portion of a process flow, in accordance with embodiments of the present disclosure.

FIGS. 4A-4D illustrate 4 views of an example of a component following the performance of a portion of a process flow, in accordance with embodiments of the present disclosure.

FIGS. 5A-5D illustrate 4 views of an example of a component following the performance of a portion of a process flow, in accordance with embodiments of the present disclosure.

FIGS. 6A-6D illustrate 4 views of an example of a component following the performance of a portion of a process flow, in accordance with embodiments of the present disclosure.

FIGS. 7A-7D illustrate 4 views of an example of a component following the performance of a portion of a process flow, in accordance with embodiments of the present disclosure.

FIGS. 8A-8D illustrate 4 views of an example of a component following the performance of a portion of a process flow, in accordance with embodiments of the present disclosure.

FIGS. 9A-9D illustrate 4 views of an example of a component following the performance of a portion of a process flow, in accordance with embodiments of the present disclosure.

FIGS. 10A-10D illustrate 4 views of an example of a component following the performance of a portion of a process flow, in accordance with embodiments of the present disclosure.

FIGS. 11A-11D illustrate 4 views of an example of a component following the performance of a portion of a process flow, in accordance with embodiments of the present disclosure.

FIGS. 12A-12D illustrate 4 views of an example of a component following the performance of a portion of a process flow, in accordance with embodiments of the present disclosure.

FIGS. 13A-13D illustrate 4 views of an example of a component following the performance of a portion of a process flow, in accordance with embodiments of the present disclosure.

FIGS. 14A-14D illustrate 4 views of an example of a component following the performance of a portion of a process flow, in accordance with embodiments of the present disclosure.

### DETAILED DESCRIPTION

Embodiments include a vertically stacked transistor component, comprising: a first layer comprising a first active region; a second layer coupled beneath the first layer, the second layer comprising a second active region, wherein the second active region is shifted with respect to the first active region; a bottom source/drain contact via partially etched through a gate connector located in the second layer; a self-aligned isolation liner located within the bottom source/drain contact via; and a bottom source/drain contact located within the self-aligned isolation liner, wherein the bottom source/drain contact is electronically isolated from the gate connector by the self-aligned isolation liner. As a result, these illustrative embodiments provide a technical effect of electronically isolating the bottom source/drain contact from the gate connector with the self-aligned isolation liner.

Some embodiments further comprise a backside contact coupled between a top source/drain located in the first layer and a backside interconnect beneath the second layer. As a result, these illustrative embodiments provide a technical effect of electronically isolating the bottom source/drain contact from the gate connector with the self-aligned isolation liner.

In some embodiments, the backside contact is electronically isolated from the bottom source/drain contact by the self-aligned isolation liner. As a result, these illustrative embodiments provide a technical effect of electronically isolating the backside contact from the bottom source/drain contact with the self-aligned isolation liner.

In some embodiments, the self-aligned isolation liner also electronically isolates a top source/drain located in the first layer from the source/drain contact. As a result, these illustrative embodiments provide a technical effect of electronically isolating the bottom source/drain contact from the gate connector with the self-aligned isolation liner.

In some embodiments, the self-aligned isolation liner comprises a dielectric material having a dielectric constant less than approximately 7. As a result, these illustrative embodiments provide a technical effect of electronically isolating the bottom source/drain contact from the gate connector with the self-aligned isolation liner.

In some embodiments, the self-aligned isolation liner comprises at least one of SiN, SiBCN, and SiOCN. As a result, these illustrative embodiments provide a technical effect of electronically isolating the bottom source/drain contact from the gate connector with the self-aligned isolation liner.

In some embodiments, the gate connector comprises at least one of Ti and TiN. As a result, these illustrative embodiments provide a technical effect of electronically isolating the bottom source/drain contact from the gate connector with the self-aligned isolation liner.

Embodiments include a semiconductor device, comprising: a first layer comprising a first active region; a second layer coupled beneath the first layer, the second layer comprising a second active region, wherein the second active region is shifted with respect to the first active region; a bottom contact via partially etched through a connector located in the second layer; a self-aligned isolation liner located within the bottom contact via; and a contact located within the self-aligned isolation liner, wherein the contact is electronically isolated from the connector by the self-aligned isolation liner. As a result, these illustrative embodiments provide a technical effect of electronically isolating the bottom source/drain contact from the gate connector with the self-aligned isolation liner.

Some embodiments further comprise a backside contact coupled between a top source/drain located in the first layer and a backside interconnect beneath the second layer. As a result, these illustrative embodiments provide a technical effect of electronically isolating the bottom source/drain contact from the gate connector with the self-aligned isolation liner.

In some embodiments, the backside contact is electronically isolated from the bottom contact by the self-aligned isolation liner. As a result, these illustrative embodiments provide a technical effect of electronically isolating the backside contact from the bottom source/drain contact with the self-aligned isolation liner.

In some embodiments, the self-aligned isolation liner also electronically isolates a top source/drain located in the first layer from the contact. As a result, these illustrative embodiments provide a technical effect of electronically isolating the bottom source/drain contact from the gate connector with the self-aligned isolation liner.

In some embodiments, the self-aligned isolation liner comprises a dielectric material having a dielectric constant less than approximately 7. As a result, these illustrative embodiments provide a technical effect of electronically isolating the bottom source/drain contact from the gate connector with the self-aligned isolation liner.

In some embodiments, the self-aligned isolation liner comprises at least one of SiN, SiBCN, and SiOCN. As a result, these illustrative embodiments provide a technical effect of electronically isolating the bottom source/drain contact from the gate connector with the self-aligned isolation liner.

In some embodiments, the connector comprises at least one of Ti and TiN. As a result, these illustrative embodiments provide a technical effect of electronically isolating the bottom source/drain contact from the gate connector with the self-aligned isolation liner.

Embodiments include a method of forming a vertically stacked transistor component, comprising: forming a bottom device layer on a substrate, the bottom device layer comprising a bottom active region; forming top device layer on the bottom device layer, the top device layer comprising a top active region, wherein the bottom active region is laterally shifted with respect to the top active region; forming a bottom source/drain contact via partially etched through a gate connector located in the bottom device layer; and forming a self-aligned isolation liner within the bottom source/drain contact via, wherein the bottom source/drain contact is electronically isolated from the gate connector by the self-aligned isolation liner. As a result, these illustrative embodiments provide a technical effect of electronically isolating the bottom source/drain contact from the gate connector with the self-aligned isolation liner.

Some embodiments further comprise forming a bottom layer source drain contact metallization within the self-aligned isolation liner. As a result, these illustrative embodiments provide a technical effect of electronically isolating the bottom source/drain contact from the gate connector with the self-aligned isolation liner.

Some embodiments further comprise forming a back end of line interconnect layer. As a result, these illustrative embodiments provide a technical effect of electronically isolating the bottom source/drain contact from the gate connector with the self-aligned isolation liner.

Some embodiments further comprise providing a carrier wafer. As a result, these illustrative embodiments provide a technical effect of electronically isolating the bottom source/drain contact from the gate connector with the self-aligned isolation liner.

Some embodiments further comprise removing the substrate, forming a backside contact coupled to a top layer source/drain, wherein the backside contact is also electronically isolated from a bottom layer source/drain by the self-aligned isolation liner. As a result, these illustrative embodiments provide a technical effect of electronically isolating the backside contact from the gate connector with the self-aligned isolation liner.

Some embodiments further comprise forming a backside interconnect on the backside contact. As a result, these illustrative embodiments provide a technical effect of electronically isolating the bottom source/drain contact from the gate connector with the self-aligned isolation liner.

Aspects of the present disclosure relate generally to the electrical, electronic, and computer fields. In particular, the present disclosure relates to components and methods for avoiding a gate connector to CR (bottom source drain contact) short. While the present disclosure is not necessarily limited to such applications, various aspects of the disclosure may be appreciated through a discussion of various examples using this context.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

The processes, steps, and structures described below do not form a complete process flow for manufacturing integrated circuits. The disclosure can be practiced in conjunction with integrated circuit fabrication techniques currently used in the art, and only so much of the commonly practiced process steps are included as necessary for an understanding of the different examples of the present disclosure. Many of the figures represent cross sections of a portion of an integrated circuit during fabrication and are not drawn to scale, but instead are drawn so as to illustrate different illustrative features of the disclosure.

In general, the various processes for a semiconductor chip or micro-chip that will be packaged into an IC fall into three general categories, namely, deposition, removal/etching, and patterning/lithography.

Deposition is any process that grows, coats, or otherwise transfers a material onto the substrate. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the substrate surface that would otherwise require higher temperatures associated with conventional CVD. Energetic ion bombardment during PECVD deposition can also improve the film's electrical and mechanical properties.

Removal/etching is any process that removes material from the substrate. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on substrates. With RIE the plasma is generated under low pressure (vacuum) by an electromagnetic field. High-energy ions from the RIE plasma attack the substrate surface and react with it to remove material.

Patterning/lithography is the formation of three-dimensional relief images or patterns on the semiconductor substrate for subsequent transfer of the pattern to a layer arranged beneath the pattern. In semiconductor lithography, the patterns are formed by a light sensitive polymer called a photoresist.

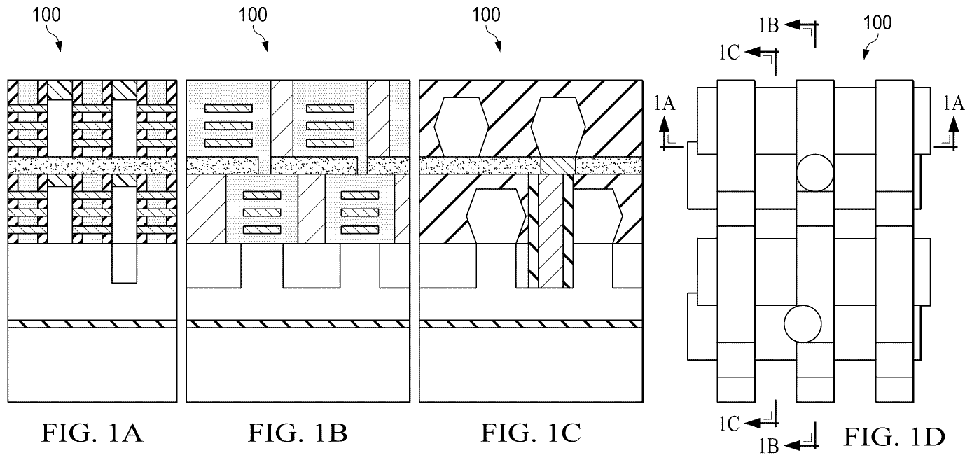

FIGS. 1A-1D show four views of a partially completed component 100. The partially completed component 100 includes structure after dummy gate removal, HfO₂ deposition, gate connector patterning, WFM/W fill and chemical mechanical planarization.

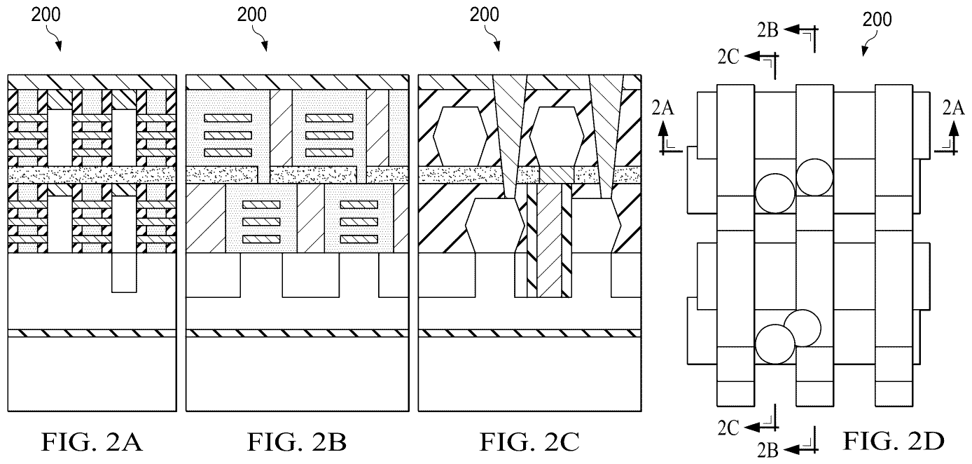

FIGS. 2A-2D show four views of a partially completed component 200. The partially completed component 200 includes structure after MOL ILD dep, and large CR (bottom source drain) via formation with non-selective etch.

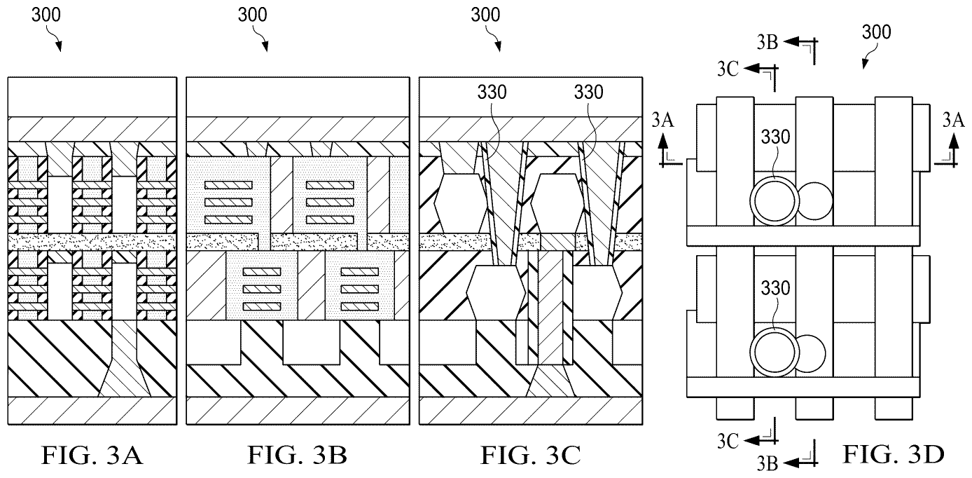

FIGS. 3A-3D show four views of a partially completed component 300. The partially completed component 300 includes structure after forming other MOL contacts and metallization. Bottom source drain contact isolation liner 330 prevents misaligned gate connector from shorting to the bottom source drain contact (CR). Bottom source drain contact isolation liner 330 also prevents BSCA2 from shorting to the bottom source drain contact (CR).

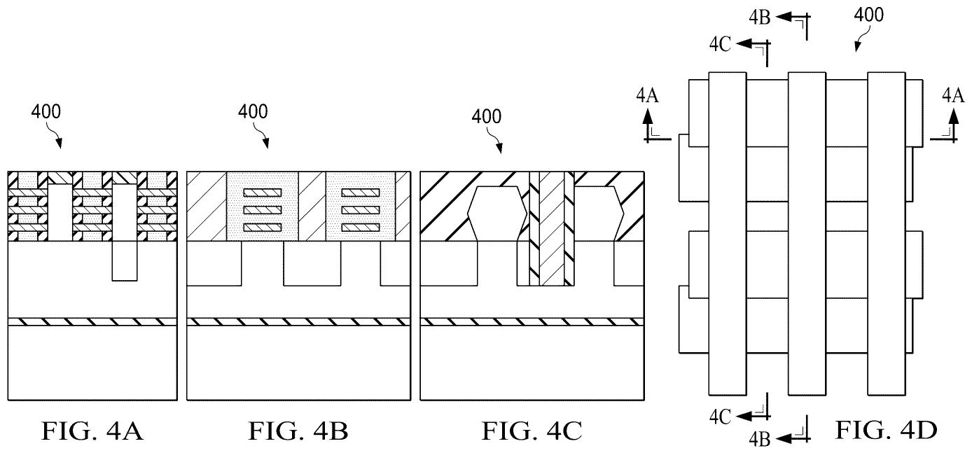

FIGS. 4A-4D show four views of a partially completed component 400. The partially completed component 400 includes structure after bottom device layer formation.

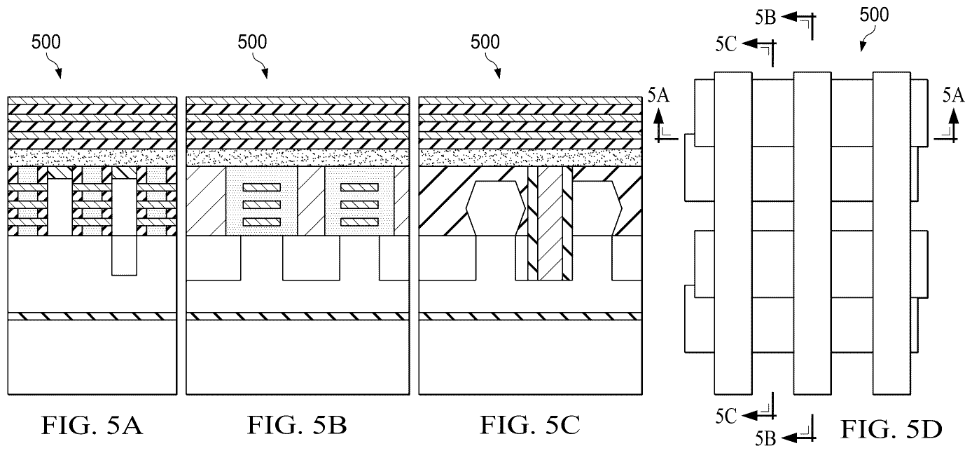

FIGS. 5A-5D show four views of a partially completed component 500. The partially completed component 500 includes structure after bonding top channel layers.

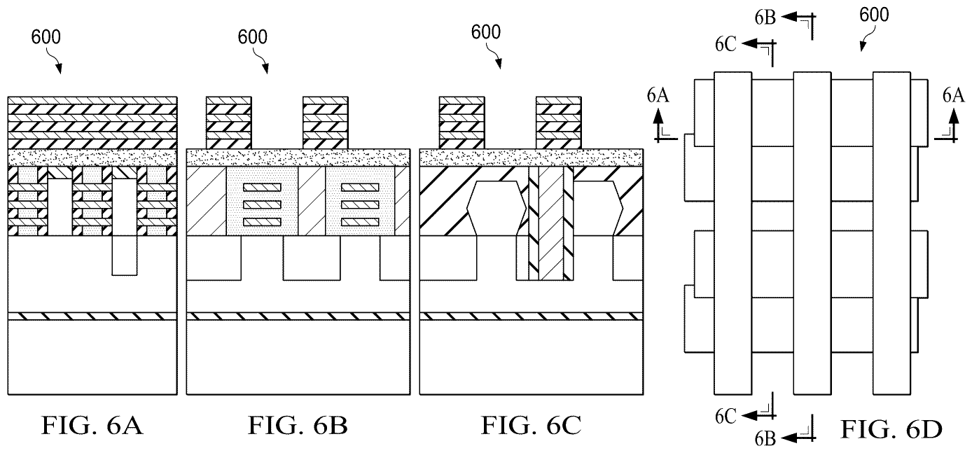

FIGS. 6A-6D show four views of a partially completed component 600. The partially completed component 600 includes structure after RY patterning.

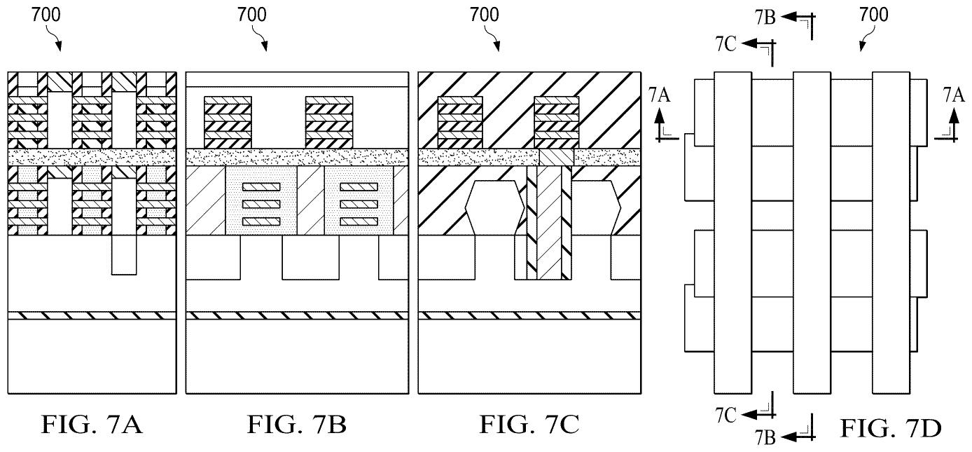

FIGS. 7A-7D show four views of a partially completed component 700. The partially completed component 700 includes structure after forming top dummy gate, spacer, inner spacer, source/drain epi, and interlayer dielectric deposition and chemical mechanical planarization.

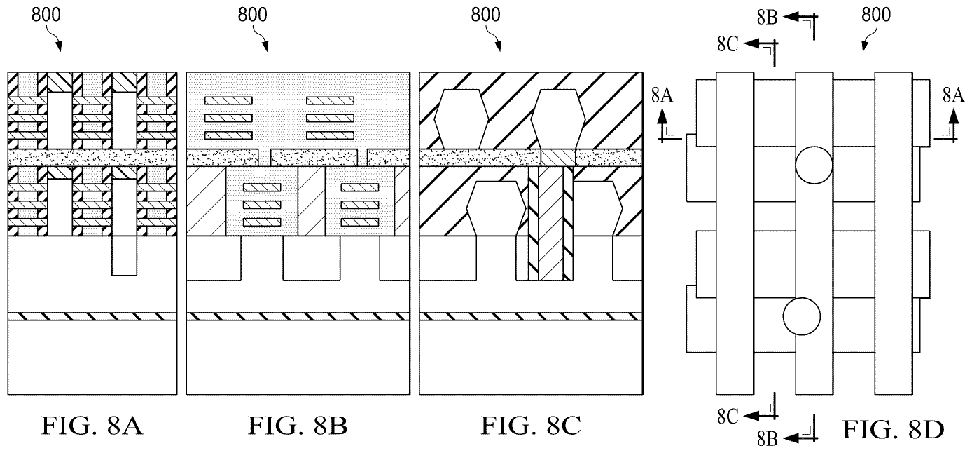

FIGS. 8A-8D show four views of a partially completed component 800. The partially completed component 800 includes structure after dummy gate removal, HfO₂ deposition, gate connector patterning, WFM/W fill and chemical mechanical planarization.

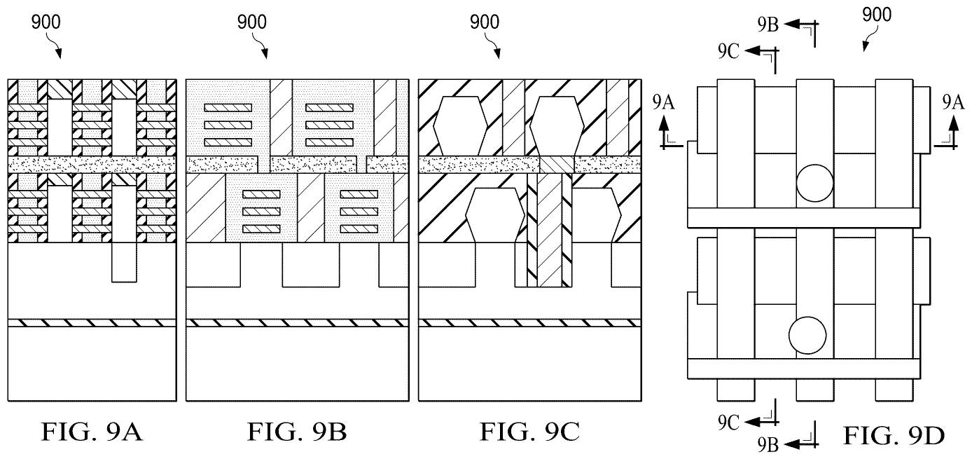

FIGS. 9A-9D show four views of a partially completed component 900. The partially completed component 900 includes structure after gate cut patterning and dielectric fill.

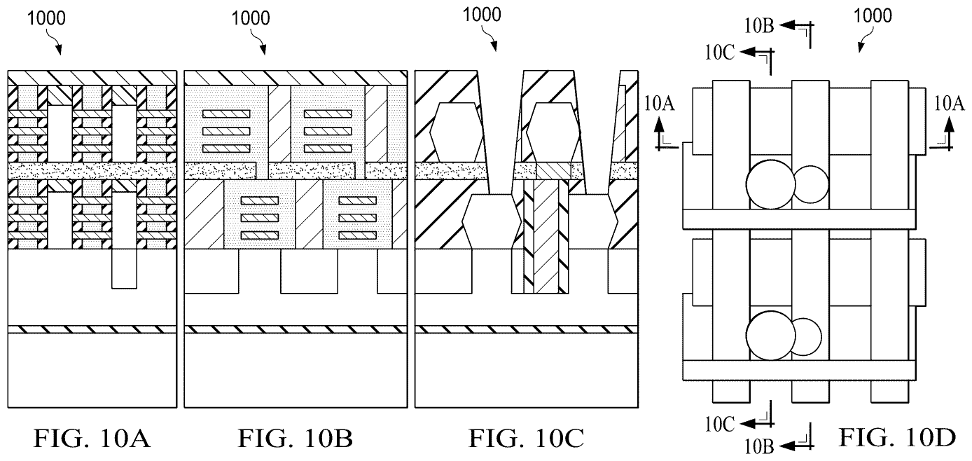

FIGS. 10A-10D show four views of a partially completed component 1000. The partially completed component 1000 includes structure after MOL ILD dep, and large CR (bottom source drain) via formation with non-selective etch.

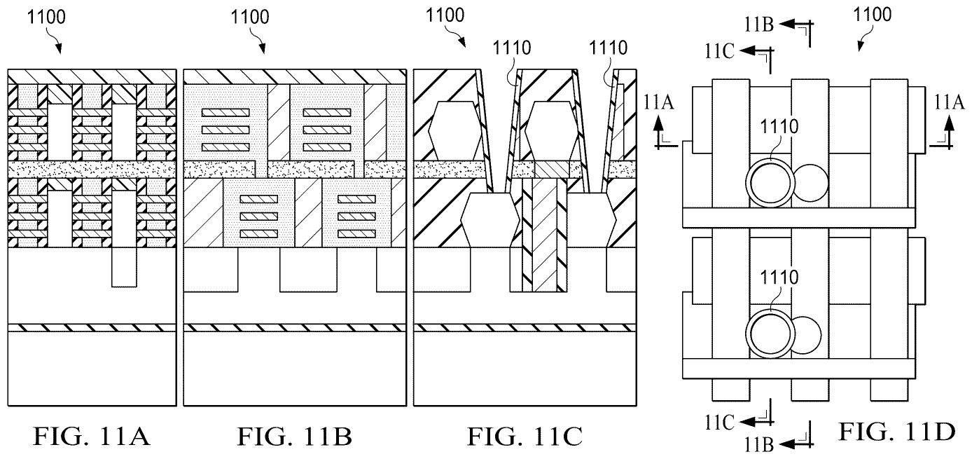

FIGS. 11A-11D show four views of a partially completed component 1100. The partially completed component 1100 includes structure after forming self-aligned isolation spacer. Bottom source drain contact isolation liner 1110 prevents misaligned gate connector from shorting to the bottom source drain contact (CR). Bottom source drain contact isolation liner 1110 also prevents BSCA2 from shorting to the bottom source drain contact (CR).

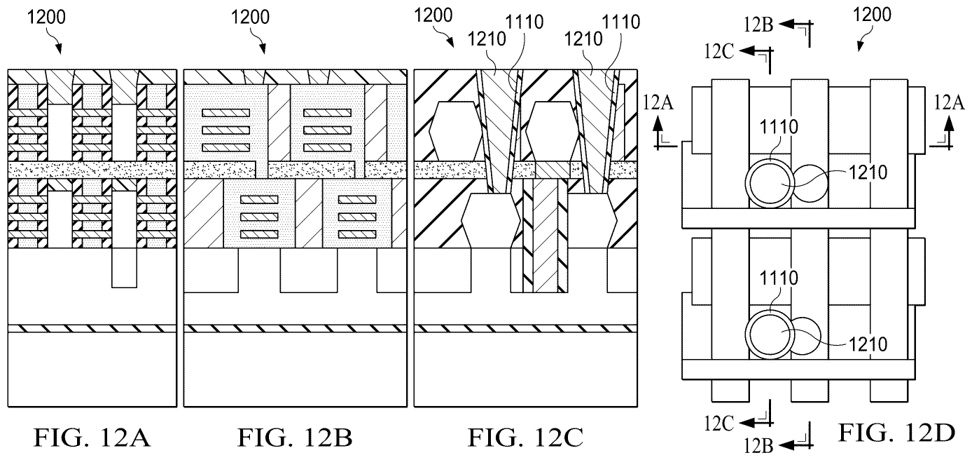

FIGS. 12A-12D show four views of a partially completed component 1200. The partially completed component 1200 includes structure after forming other MOL contacts and metallization. Bottom source drain contact 1210 is located within bottom source drain contact isolation liner 1110.

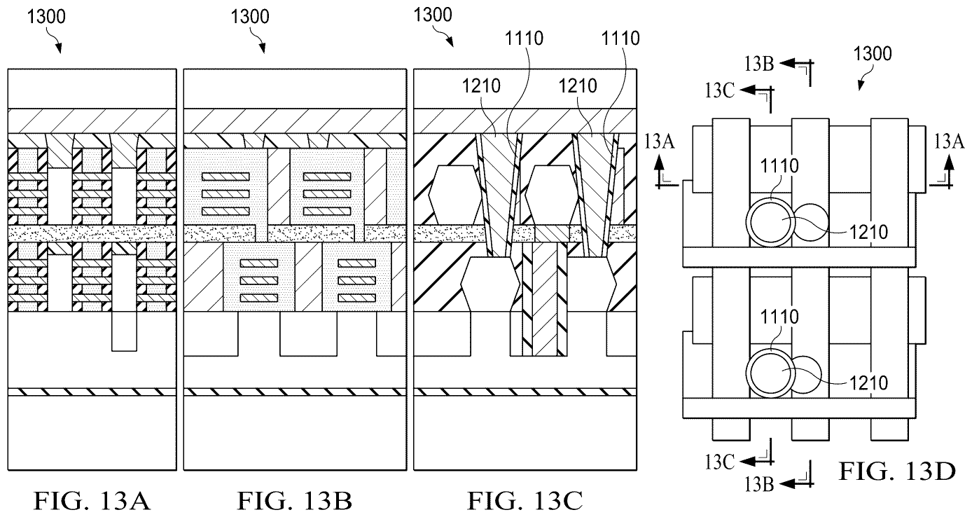

FIGS. 13A-13D show four views of a partially completed component 1300. The partially completed component 1300 includes structure after forming BEOL (back end of line) and bonding carrier wafter.

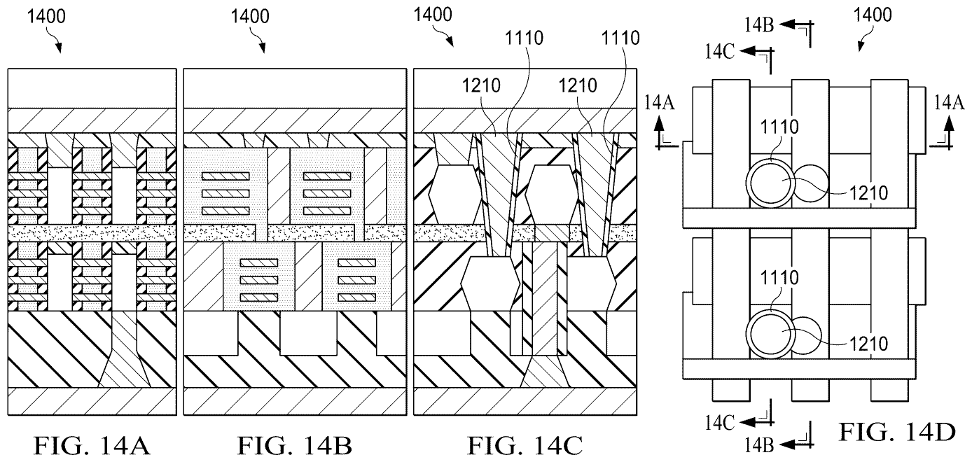

FIGS. 14A-14D show four views of a partially completed component 1400. The partially completed component 1400 includes structure after wafer flip, removing substrate, and forming backside interconnect.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding of the various embodiments. But the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C,” may include item A, item A and item B, or item B. This example also may include item A, item B, and item C, or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A vertically stacked transistor component, comprising:
a first layer comprising a first active region;
a second layer coupled beneath the first layer, the second layer comprising a second active region, wherein the second active region is shifted with respect to the first active region;
a bottom source/drain contact via partially etched through a gate connector located in the second layer;
a self-aligned isolation liner located within the bottom source/drain contact via; and
a bottom source/drain contact located within the self-aligned isolation liner,
wherein the bottom source/drain contact is electronically isolated from the gate connector by the self-aligned isolation liner.

2. The vertically stacked transistor component of claim 1, further comprising a backside contact coupled between a top source/drain located in the first layer and a backside interconnect beneath the second layer.

3. The vertically stacked transistor component of claim 2, wherein the backside contact is electronically isolated from the bottom source/drain contact by the self-aligned isolation liner.

4. The vertically stacked transistor component of claim 1, wherein the self-aligned isolation liner also electronically isolates a top source/drain located in the first layer from the source/drain contact.

5. The vertically stacked transistor component of claim 1, wherein the self-aligned isolation liner comprises a dielectric material having a dielectric constant less than approximately 7.

6. The vertically stacked transistor component of claim 5, wherein the self-aligned isolation liner comprises at least one of SiN, SiBCN, and SiOCN.

7. The vertically stacked transistor component of claim 1, wherein the gate connector comprises at least one of Ti and TiN.

8. A semiconductor device, comprising:
a first layer comprising a first active region;
a second layer coupled beneath the first layer, the second layer comprising a second active region, wherein the second active region is shifted with respect to the first active region;
a bottom contact via partially etched through a connector located in the second layer;
a self-aligned isolation liner located within the bottom contact via; and
a contact located within the self-aligned isolation liner,
wherein the contact is electronically isolated from the connector by the self-aligned isolation liner.

9. The semiconductor device of claim 8, further comprising a backside contact coupled between a top source/drain located in the first layer and a backside interconnect beneath the second layer.

10. The semiconductor device of claim 9, wherein the backside contact is electronically isolated from the bottom contact by the self-aligned isolation liner.

11. The semiconductor device of claim 8, wherein the self-aligned isolation liner also electronically isolates a top source/drain located in the first layer from the contact.

12. The semiconductor device of claim 8, wherein the self-aligned isolation liner comprises a dielectric material having a dielectric constant less than approximately 7.

13. The semiconductor device of claim 12, wherein the self-aligned isolation liner comprises at least one of SiN, SiBCN, and SiOCN.

14. The semiconductor device of claim 8, wherein the connector comprises at least one of Ti and TiN.

15. A method of forming a semiconductor device, comprising:
forming a bottom device layer on a substrate, the bottom device layer comprising a bottom active region;
forming top device layer on the bottom device layer, the top device layer comprising a top active region, wherein the bottom active region is laterally shifted with respect to the top active region;
forming a bottom source/drain contact via partially etched through a gate connector located in the bottom device layer; and
forming a self-aligned isolation liner within the bottom source/drain contact via,
wherein the bottom source/drain contact is electronically isolated from the gate connector by the self-aligned isolation liner.

16. The method of claim 15, further comprising forming a bottom layer source drain contact metallization within the self-aligned isolation liner.

17. The method of claim 16, further comprising forming a back end of line interconnect layer.

18. The method of claim 17, further comprising providing a carrier wafer.

19. The method of claim 18, further comprising removing the substrate, forming a backside contact coupled to a top layer source/drain, wherein the backside contact is also electronically isolated from a bottom layer source/drain by the self-aligned isolation liner.

20. The method of claim 19, further comprising forming a backside interconnect on the backside contact.
